(19) United States
(12) Patent Application Publication
(10) Pub. No.: US 2024/0290576 A1
(43) Pub. Date: Aug. 29, 2024

(54) ION BEAM EXTRACTION ELECTRODE, ION SOURCE AND EXTRACTION ELECTRODE STRUCTURE

(71) Applicant: NISSIN ION EQUIPMENT CO., LTD., Koka-city (JP)

(72) Inventors: Yuya HIRAI, Koka-city (JP); Weijang ZHAO, Koka-city (JP)

(73) Assignee: NISSIN ION EQUIPMENT CO., LTD., Koka-city (JP)

(21) Appl. No.: 18/464,744

(22) Filed: Sep. 11, 2023

(30) Foreign Application Priority Data
Feb. 28, 2023 (JP) 2023-030064

(51) Int. Cl. H01J 37/317; H01J 37/08; H01J 37/30

(52) U.S. Cl. CPC H01J 37/3171; H01J 37/08; H01J 37/3002; H01J 2237/006

(57) ABSTRACT

An ion beam extraction electrode includes a first member including a first beam passage hole through which an ion beam passes, a second member positioned opposite the first member and including a second beam passage hole through which the ion beam passes, a heater partially or fully disposed between the first member and the second member, and a gas shutoff member that blocks a flow of a gas from entering a space between the first member and the second member.

### CROSS-REFERENCE TO RELATED APPLICATION

This application claims priority from Japanese Patent Application No. 2023-30064, filed in the Japanese Patent Office on Feb. 28, 2023, the contents thereof being herein incorporated by reference in its entirety.

### BACKGROUND

### 1. Field

The present disclosure relates to an ion beam extraction electrode, an ion source, and an extraction electrode structure.

### 2. Description of Related Art

Some ion sources used in an ion beam irradiation apparatus and other devices are equipped with an extraction electrode unit consisting of multiple electrodes to extract an ion beam from a plasma chamber.

If deposits continue to accumulate on the extraction electrode unit, the deposits may be given an electric charge from the ion beam, resulting in a discharge.

### SUMMARY

According to an aspect of one or more embodiments, there is provided an ion beam extraction electrode comprising a first member including a first beam passage hole through which an ion beam passes, a second member positioned opposite the first member and including a second beam passage hole through which the ion beam passes, a heater at least partially disposed between the first member and the second member; and a gas shutoff member that blocks a flow of a gas from entering a space between the first member and the second member.

According to another aspect of one or more embodiments, there is provided an ion beam extraction structure comprising a first electrode comprising a first member with a first beam passage hole through which an ion beam passes, and a second member positioned opposite the first member and having a second beam passage hole; a second electrode; a heater at least partially disposed between the first member and the second member; and a gas shutoff member that blocks a flow of gas from entering a space between the first member and the second member.

According to another aspect of one or more embodiments, there is provided a ion beam extraction electrode comprising a first member including a first beam passage hole through which an ion beam passes, a second member positioned opposite the first member and including a second beam passage hole through which the ion beam passes, the first member and the second member defining a space therebetween; and a heater disposed in the space, wherein the heater contacts at least a portion of the first member.

According to another aspect of one or more embodiments, there is provided an ion beam extraction electrode comprising a first member including a first beam passage hole through which an ion beam passes, a second member positioned opposite the first member and including a second beam passage hole through which the ion beam passes, means for heating at least one of the first member and the second member and for blocking a flow of gas from entering a space between the first member and the second member.

### BRIEF DESCRIPTION OF THE DRAWINGS

The above and/or other aspects will become apparent and more readily appreciated from the following description of embodiments, taken in conjunction with the accompanying drawings, in which:

FIG. 1 is a schematic diagram showing an ion source according to some embodiments;

FIG. 2 is a schematic cross-sectional diagram showing a configuration of a suppression electrode, according to some embodiments;

FIG. 3 is a schematic cross-sectional diagram showing a configuration of a suppression electrode, according to some embodiments;

FIG. 4 is a schematic exploded diagram showing a configuration of a suppression electrode, according to some embodiments;

FIG. 5 is a schematic diagram showing an arrangement of heaters, according to some embodiments;

FIGS. 6A and 6B are schematic diagrams showing an arrangement of heaters, according to some embodiments;

FIG. 7 is a schematic diagram showing an arrangement of heaters, according to some embodiments; and

FIG. 8 is a schematic cross-sectional diagram showing a configuration of a suppression electrode, according to some embodiments.

### DETAILED DESCRIPTION

Some ion sources are equipped with a heater that heats an extraction electrode unit to suppress deposits on the extraction electrode unit having a suppression electrode and a ground electrode.

Specifically, the heater is placed between the suppression electrode and the ground electrode, which constitute the extraction electrode unit.

This ion source is configured to allow gases used during operation of the ion source, such as gases for generating a plasma and gases for sputtering a wafer, to flow into the space where the heater is located.

In this configuration, there is a disadvantage in that an internal pressure of the space may increase due to heating of the gas that flows in, causing various problems such as damage to the electrodes, misalignment of the electrodes, and a spark discharge between the electrodes.

It is an aspect to make it possible to reduce deposits on the extraction electrode and to address the above problems. However, various embodiments herein are not required to overcome the problems and disadvantages discussed above, and some embodiments may not overcome any of the disadvantages described above.

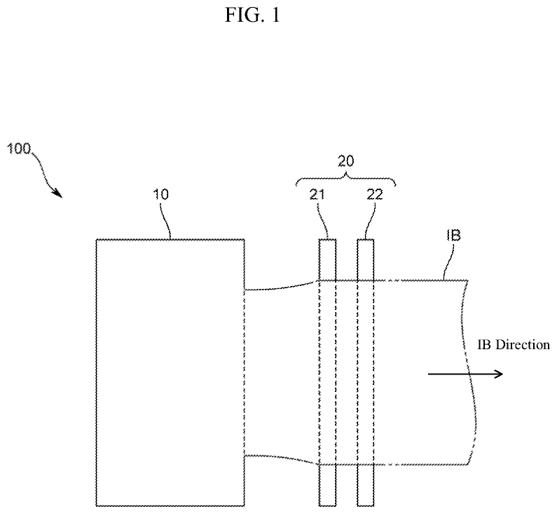

FIG. 1 is a schematic diagram showing an ion source according to some embodiments. An ion source 100 may be included in an ion beam irradiation apparatus. An example of an ion beam irradiation apparatus is an ion implanter for implanting desired ion species into a wafer by irradiating a surface of a substrate with an ion beam IB, but embodiments are not necessarily limited to this and, in some embodiments, the ion source 100 may be included in an ion beam etching device or the like.

As shown in FIG. 1, the ion source 100 has a chamber 10 and an extraction electrode structure 20 that extracts an ion beam IB from an opening in the chamber 10.

The chamber 10 is a chamber to which corrosive gases are supplied, such as gases for generating a plasma, gases for sputtering a wafer used to sputter materials, or gases that react with solid metals in a crucible to produce vapor of reaction products including metals by heating the crucible.

Since a plasma is generated inside the chamber, the chamber is called a plasma generating chamber. However, the chamber 10 does not necessarily need to be supplied with corrosive gases, and various gases can be supplied.

The extraction electrode structure 20, as shown in FIG. 1, has a plurality of ion beam extraction electrodes, and in the embodiment illustrated in FIG. 1, the extraction electrode structure 20 comprises two ion beam extraction electrodes. One is a suppression electrode 21 that suppresses inflow of secondary electrons to the chamber 10 side. Another is a ground electrode 22 that determines a ground potential. In some embodiments, the extract electrode structure 20 may consist of the two ion beam extraction electrodes.

Since the ion source 100 of the embodiment illustrated in FIG. 1 is characterized by the suppression electrode 21, the suppression electrode 21 is described in detail below.

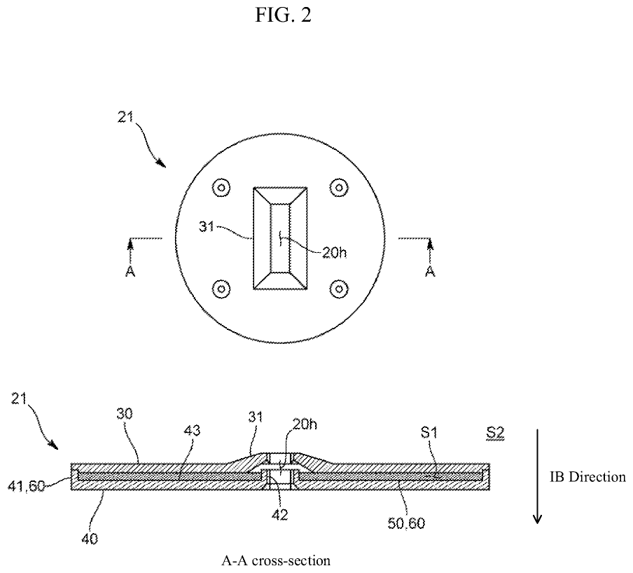

FIG. 2 is a schematic cross-sectional diagram showing a configuration of a suppression electrode, according to some embodiments. The suppression electrode 21, to which a negative voltage is applied with respect to the ground potential, for example, has a beam passage hole 20h through which the ion beam IB extracted from the chamber 10 passes.

In more detail, the suppression electrode 21 has a lid 30 as a first member disposed opposite an opening of the chamber 10 and a bottom plate 40 as a second member disposed opposite the lid 30.

As shown in FIG. 2, the lid 30 is plate-shaped with a portion of the beam passage hole 20h formed in its center, and in the embodiment illustrated in FIG. 2, the lid 30 has a circular shape viewed from the direction of travel of the ion beam IB. However, the lid 30 is not limited to a circular shape, and in some embodiments may be rectangular as viewed from the direction of travel of the ion beam IB.

The lid 30 of the embodiment illustrated in FIG. 2 surrounds the beam passage hole 20h and has a slightly bent portion 31 that is bent toward the chamber 10 side.

The bottom plate 40 is plate-shaped with a portion of the beam passage hole 20h formed in its center, and is fixed to the lid 30 by fasteners such as bolts, for example.

The bottom plate 40 of the embodiment illustrated in FIG. 2 has an outer edge 41 and an inner edge 42 each protruding toward the lid 30. An annular recess 43 is formed surrounding the beam passage hole 20h between the outer edge 41 and the inner edge 42.

A portion of the beam passage hole 20h formed in the lid 30 and a portion of the beam passage hole 20h formed in the bottom plate 40 overlap each other as viewed from the direction of the ion beam IB, and here the portions form a rectangular shape. However, the shape and size of the beam passage holes 20h are not particularly limited and may be changed.

The suppression electrode 21 in FIG. 2 has a heater 50 interposed between the lid 30 and the bottom plate 40. The heater 50 may heat at least one of the lid 30 and the bottom plate 40.

More specifically, a heater installation space S1 is formed between the bottom plate 40 and the lid 30, which surrounds the beam passage hole 20h and where at least a part of the heater 50 is located.

The heater installation space S1 is an annular space formed by using the recesses in the bottom plate 40 described above. In FIG. 2, the heater 50 is annular and the heater 50 is entirely housed in the heater installation space S1.

The heater 50 is sheet-shaped and specifically has an insulating layer (not shown) and a pattern layer (not shown) on the insulating layer with a wiring pattern in which electric current flows.

Thus, the suppression electrode 21 of the embodiment illustrated in FIG. 2 is equipped with a gas shutoff member 60 that blocks a flow of gas between the lid 30 and the bottom plate 40 from the beam passage hole 20h. Here, the gas shutoff member 60 may correspond to the heater 50 that substantially fills the heater installation space S1 between the lid 30 and the bottom plate 40. In other words, because the heater 50 substantially fills the heater installation space S1, the gas cannot flow into the space S1 between the lid 30 and the bottom plate 40 and thereby create an increase in pressure between the lid 30 and the bottom plate 40.

The gas shutoff member 60 prevents problems caused by gas flowing into the heater installation space S1. Such defects can be caused by the internal pressure of the heater installation space S1 increasing due to heating of the gas flowing into the space S1. Specifically, the problems include damage to the suppression electrode 21, misalignment of the suppression electrode 21, and spark discharges that may occur between the lid 30 and the bottom plate 40. Another defect is corrosion of the heater 50 due to the use of corrosive gases.

The gas shutoff member 60 blocks the flow of gas that tries to flow from the ambient space S2 around the suppression electrode 21 through the beam passage hole 20h into the heater installation space S1.

The ambient space S2 includes at least the space between the chamber 10 and the extraction electrode structure 20. In other words, the ambient space S2 includes the space into which the gas supplied to the chamber 10 leaks out.

In the embodiment illustrated in FIG. 2, the heater 50 is embedded between the lid 30 and the bottom plate 40, and serves as the gas shutoff member 60.

Specifically, the gas shutoff member 60 is sandwiched between the lid 30 and the bottom plate 40.

As a result, the heater 50, as the gas shutoff member 60, blocks the flow of gas that tries to flow from the ambient space S2 through the beam passage hole 20h and between the lid 30 and the bottom plate 40 as described above.

Furthermore, the outer edge 41 of the bottom plate 40 described above is in contact with the lid 30, and in some embodiments, the outer edge 41 may also serve as a portion of the gas shutoff member 60.

The outer edge 41 surrounds the heater installation space S1 and blocks the flow of gas that tries to flow between the lid 30 and the bottom plate 40 from outside the suppression electrode 21 without passing through the beam passage hole 20h. That is, the outer edge 41 blocks gas that might otherwise flow from ambient space S2 at the sides of the suppression electrode 21 into the space between the lid 30 and the bottom plate 40.

According to this configuration of the suppression electrode 21, the deposits can be suppressed by heating with the heater 50. Furthermore, since gas flow between the lid 30 and the bottom plate 40 is blocked by the gas shutoff member 60, various problems associated with this gas flow can be prevented.

Additionally, uniform heating in the heater installation space S1 can be performed, because the heater 50 wholly occupies the heater installation space S1.

Furthermore, the suppression electrode 21 can be made more compact, because the heater 50 forms a sheet.

Because the heater 50 is provided between lid 30 and bottom plate 40, the voltage that the heater 50 can withstand can be ensured with a relatively simple configuration by, for example, interposing an insulating material between the heater 50 and the bottom plate 40 and/or between the heater 50 and the lid 30.

In some embodiments, the outer edge 41 of the bottom plate 40 may function as a portion of the gas shutoff member 60, so a gas flow between the lid 30 and bottom plate 40 can be shut off more reliably.

In the ion source 100 of the embodiment illustrated in FIG. 2, in which a corrosive gas is supplied to the chamber 10, the function of the heater 50 as the gas shutoff member 60 is more remarkable. The function of the heater 50 as the gas shutoff member 60 reduces corrosive effects of the corrosive gas on the heater 50, which contributes to various ion beam irradiation processes in which the corrosive gas is used.

For example, the embodiment illustrated in FIG. 2 and described above describes the suppression electrode 21 as including the heater 50. However, in some embodiments, the grounding electrode 22 that is included in the extraction electrode structure 20 may be equipped with the heater 50 and the gas shutoff member 60, similar to the suppression electrode 21.

As for the ion source 100, in some embodiments, the extraction electrode structure 20 may include three or more electrodes, and in this case, one or more electrodes may be equipped with the heater 50 and the gas shutoff member 60, similar to the suppressing electrode 21 in the embodiment illustrated and described with respect to FIG. 2.

The suppression electrode 21 of the embodiment illustrated in FIG. 2 is equipped with the heater 50 which is a single piece, but in some embodiments, the heater 50 may have multiple pieces, i.e., a plurality of heaters 50. In this case, the heaters 50 may be housed between the lid 30 and bottom plate 40, or some of the plurality of heaters 50 may be outside the area between the lid 30 and bottom plate 40.

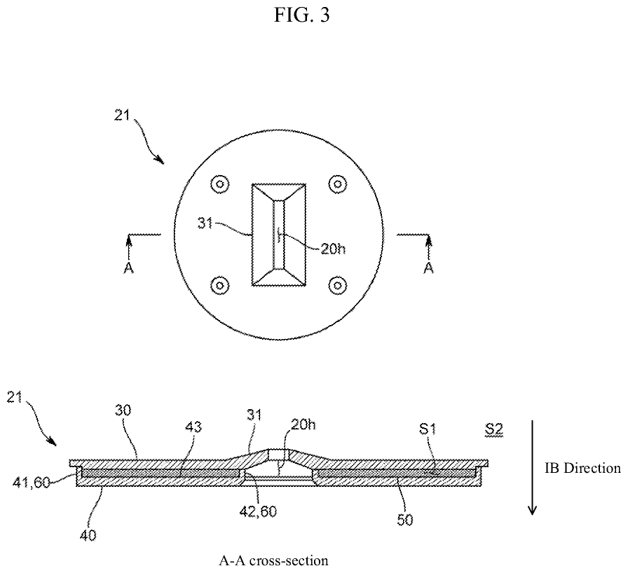

In the embodiment illustrated in FIG. 2, the heater installation space S1 and the ambient space S2 are connected, but as shown in FIG. 3, the space S1 between the lid 30 and the bottom plate 40 may be sealed by the gas shutoff member 60 and spatially separated from the ambient space S2.

FIG. 3 is a schematic cross-sectional diagram showing a configuration of a suppression electrode, according to some embodiments. The bottom plate 40 in the embodiment illustrated in FIG. 3 protrudes toward and is in contact with the lid 30, and in this case, the inner edge 42 may correspond to the gas shutoff member 60. The lid 30 may extend radially beyond the outer edge 41 of the bottom plate 40, as illustrated in FIG. 3 Thus, the outer edge 41 of the bottom plate 40 may correspond to the gas shutoff member 60, as in the embodiment illustrated with respect to FIG. 2. As a result, the space S1 between the lid 30 and the bottom plate 40 is sealed, making it impossible for a gas to flow into the space between the lid 30 and the bottom plate 40 from the ambient space S2. In other words, in the embodiment illustrated in FIG. 3, the gas shutoff member 60 may include the inner edge 42 and the outer edge 41 of the bottom plate 40.

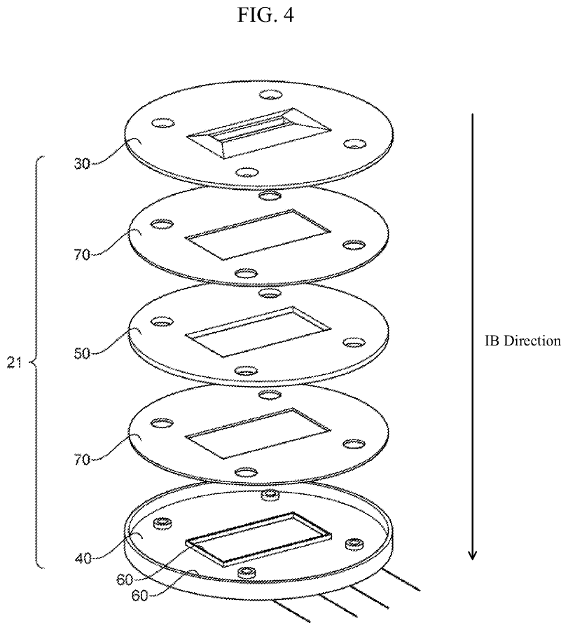

The suppression electrode 21 may be further provided with an insulating member 70 interposed between the heater 50 and the lid 30 and/or between the heater 50 and the bottom plate 40, as shown in FIG. 4. It is noted that FIG. 4 shows an example in which the insulating member 70 is interposed between the heater 50 and the lid 30 and between the heater 50 and the bottom plate 40. However, this configuration is only an example and, in some embodiment, one of the insulating members 70 may be omitted.

The insulating member 70 is a heat-resistant, flat plate, for example, and can be specifically made of ceramics such as alumina.

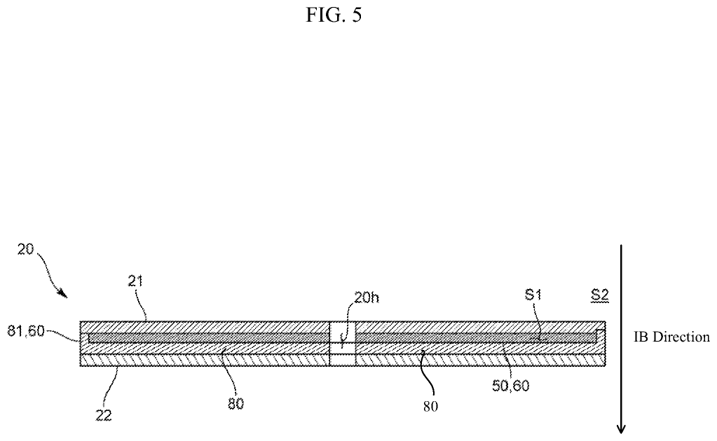

In the embodiments illustrated with respect to FIGS. 2-4, the suppression electrode 21 was divided into the lid 30 and the bottom plate 40, and the heater 50 was interposed between the lid 30 and the bottom plate 40, but as shown in FIG. 5, in some embodiments, the heater 50 may be interposed between the suppression electrode 21 and the grounding electrode 22.

FIG. 5 is a schematic diagram showing an arrangement of heaters, according to some embodiments. In FIG. 5, the first member may be the suppression electrode 21 and the second member may be the grounding electrode 22, and the heater 50, which is the gas shutoff member 60, blocks the gas flow between the suppression electrode 21 and the grounding electrode 22.

In this configuration, the extraction electrode structure 20 has at least two electrodes, the first member and the second member, the heater 50 interposed between the electrodes, and the gas shutoff member 60 that blocks the flow of gas between these electrodes.

The at least two electrodes are not necessarily limited to the suppression electrode 21 and the grounding electrode 22. For example, in some embodiments, the extraction electrode structure 20 may include a plasma electrode, an acceleration electrode, a suppression electrode, and a ground electrode in order from the chamber 10 in the direction of ion beam extraction. In this configuration, one or more of the plasma electrode, the acceleration electrode, the acceleration electrode and the suppression electrode, etc. may be modified according to the configurations of the suppression electrode 21 and the ground electrode 22 in one of the aforementioned examples.

In the embodiment illustrated in FIG. 5, it is advantageous to interpose an insulating member 80 between the heater 50 and the suppression electrode 21 and/or between the heater 50 and the grounding electrode 22. In FIG. 5, the pattern layer (not shown) of the heater 50 is provided on the grounding electrode 22 side (i.e., that pattern layer that includes a wiring pattern faces the grounding electrode 22), and an insulator, e.g. the insulating member 80, is interposed between the heater 50 and the grounding electrode 22.

The insulating member 80 has an outer edge 81 in contact with the suppression electrode 21 and the grounding electrode 22. The outer edge 81 blocks the flow of gas between the suppression electrode 21 and the grounding electrode 22. Thus, the gas shutoff member 60 may include the outer edge 81 in the embodiment illustrated in FIG. 5.

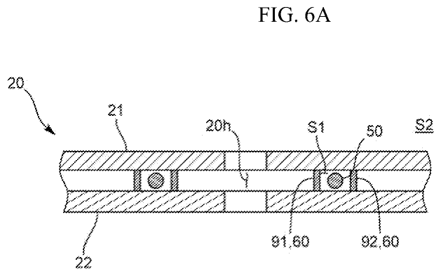

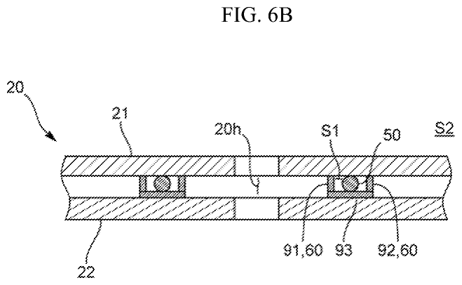

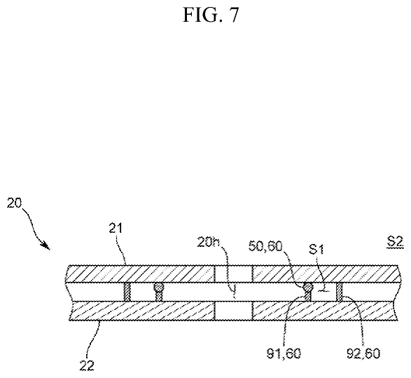

The heater 50 is not limited to a sheet-shaped heater, and in some embodiments, the heater 50 may be rod-shaped (bar-shaped) or wire-shaped, as shown in FIGS. 6 and 7.

FIGS. 6A and 6B are schematic diagrams showing an arrangement of heaters, according to some embodiments, and FIG. 7 is a schematic diagram showing an arrangement of heaters, according to some embodiments. In FIG. 6A, the extraction electrode structure 20 may include a first insulating member 91 and a second insulating member 92 between the suppression electrode 21 and the grounding electrode 22. The first and second insulating members 91 and 92 may be annular in shape. The first insulating member 91 may be located radially outward from the beam passage hole 20h, and the second insulating member 92 may be located further radially outward than the first insulating member 91.

The heater 50 may be placed in the annular space formed between the first and second insulating members 91 and 92.

In the configuration described with respect to FIG. 6A, the gas shutoff member 60 may include the first insulating member 91 and the second insulating member 92 since the first insulating member 91 and the second insulating member 92 shut off the flow of gas between the suppression electrode 21 and the grounding electrode 22. Here, the first insulating member 91 and the second insulating member 92, which are the gas shutoff members 60, shut off the flow of gas into the annular heater installation space S1 where the heater 50 is arranged.

In some embodiments, to ensure insulation between the heater 50 and the grounding electrode 22, the extraction electrode structure 20 may further include a third insulating member 93, may be provided between the heater 50 and the grounding electrode 22, as shown in FIG. 6B. In this configuration, the gas shutoff member 60 may include the first to third insulating members 91 to 93. Although not shown in FIG. 6B, in some embodiments, to ensure insulation between the heater 50 and the suppression electrode 21, a fourth insulating member may be provided between the heater 50 and the suppression electrode 21. In other words, insulating members may be provided to surround the heater 50 on all sides. In such a configuration, the gas shutoff member 60 may include the first to fourth insulating members. As shown in FIG. 6A, in embodiments in which the heater 50 can be electrically floated from the suppression electrode 21 and the grounding electrode 22, the third insulating member 93 and the fourth insulating member may be omitted.

Furthermore, as shown in FIG. 7, a configuration in which a gas touches the heater 50 is acceptable if an adverse effect of the gas on the heater 50 is negligible, such as when the gas is not corrosive.

Specifically, the heater 50 may be interposed between the first insulating member 91 and the suppression electrode 21, between the first insulating member 91 and the grounding electrode 22, between the second insulating member 92 and the suppression electrode 21, and/or between the second insulating member 92 and the grounding electrode 22. The embodiment illustrated in FIG. 7 shows the heater 50 interposed between the first insulating member 91 and the suppression electrode 21 by way of example. In this case, the gas shutoff member 60 may include the first insulating member 91, the second insulating member 92, and the heater 50 since the first insulating member 91, the second insulating member 92, and the heater 50 block the flow of gas between the suppression electrode 21 and the grounding electrode 22.

In some embodiments, the heater 50 or insulator(s) described in the embodiments of FIG. 6A, FIG. 6B or FIG. 7 may be placed between the lid 30 and bottom plate 40, which constitute the suppression electrode 21 of FIG. 2 through FIG. 5.

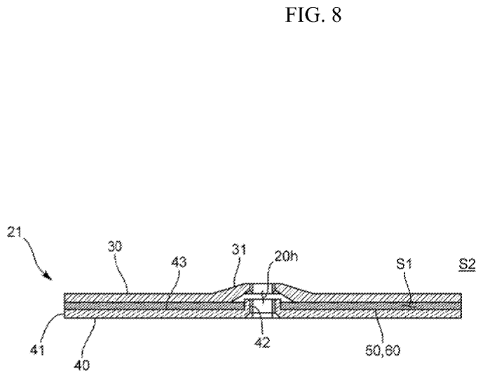

In the suppression electrode 21 of the embodiments of FIGS. 2-3, the outer edge 41 of the bottom plate 40 was in contact with the lid 30 and functioned as the gas shutoff member 60, but as shown in FIG. 8, the outer periphery of the heater 50 can be exposed.

FIG. 8 is a schematic cross-sectional diagram showing a configuration of a suppression electrode, according to some embodiments. In the case where the heater 50 is provided between at least two electrodes of the extraction electrode structure 20, the outer periphery of the heater 50 may be exposed. In such a configuration, the gas shutoff member 60 may include the heater 50.

It should be understood that the present disclosure is not limited to the above embodiments, but various other changes and modifications may be made therein without departing from the spirit and scope thereof as set forth in appended claims.

What is claimed is:

1. An ion beam extraction electrode comprising:
a first member including a first beam passage hole through which an ion beam passes,
a second member positioned opposite the first member and including a second beam passage hole through which the ion beam passes,
a heater at least partially disposed between the first member and the second member; and
a gas shutoff member that blocks a flow of a gas from entering a space between the first member and the second member.

2. The ion beam extraction electrode according to claim 1, wherein the heater is sheet-shaped.

3. The ion beam extraction electrode according to claim 1, wherein:
the first member is a lid that is a component of a single electrode,
the second member is a bottom plate that is covered by the lid and together with the lid, constitutes the ion beam extraction electrode, and
the heater is embedded between the lid and the bottom plate to serve as the gas shutoff member.

4. The ion beam extraction electrode according to claim 1, wherein the first member and the second member are spatially separated from a surrounding space around the first member and the second member.

5. An ion source comprising:
the ion beam extraction electrode according to claim 1;
a chamber, from which the ion beam is extracted by the ion beam extraction electrode,
wherein a corrosive gas is supplied to the chamber.

6. An ion beam extraction electrode comprising:
a first member including a first beam passage hole through which an ion beam passes,
a second member positioned opposite the first member and including a second beam passage hole through which the ion beam passes, the first member and the second member defining a space therebetween; and
a heater disposed in the space,
wherein the heater contacts at least a portion of the first member.

7. The ion beam extraction electrode of claim 6, wherein the heater contacts at least a portion of the second member.

8. The ion beam extraction electrode of claim 6, wherein the first member comprises a protrusion that protrudes away from the second member, and the first beam passage hole is disposed in the protrusion.

9. The ion beam extraction electrode of claim 6, wherein the second member includes an outer edge portion that further defines the space between the first member and the second member,
the heater directly contacts the at least a portion of the first member, at least a portion of the second member and the outer edge portion, and
the outer edge portion blocks a flow of gas that is ambient to the ion beam extraction electrode from flowing into the space.

10. The ion beam extraction electrode of claim 6, wherein the second member includes an inner edge portion that defines the second beam passage hole, and an outer edge portion,
the inner edge and the outer edge further define the space,
the heater directly contacts the at least a portion of the first member, the second member, the inner edge portion, and the outer edge portion,
the inner edge portion blocks a flow of gas from the first beam passage hole and the second beam passage hole into the space, and
the outer edge portion blocks a flow of gas that is ambient to the ion beam extraction electrode from flowing into the space.

11. An ion beam extraction structure comprising:
the ion beam extraction electrode of claim 6; and
an insulating member disposed between the heater and the second member in the space, the insulating member comprising an outer edge portion,
wherein the heater directly contacts the at least a portion of the first member, the insulating member and the outer edge portion of the insulating member, and
wherein the outer edge portion blocks a flow of gas that is ambient to the ion beam extraction structure from flowing into the space.

12. An ion beam extraction structure comprising:
the ion beam extraction electrode of claim 6; and
a first insulating member disposed radially outward from the first beam passage hole and the second beam passage hole; and
a second insulating member disposed further radially outward than the first insulating member,
wherein the heater is disposed in the space between the first insulating member and the second insulating member,
wherein the first insulating member blocks the flow of gas from the first beam passage hole and the second beam passage hole into the space, and
wherein the second insulating member blocks a flow of gas that is ambient to the ion beam extraction structure from flowing into the space.

13. An ion beam extraction structure of claim 11, further comprising a third insulating member disposed between the heater and the second member, between the first insulating member and the second member and between the second insulating member and the second member.

14. An ion beam extraction electrode comprising:
a first member including a first beam passage hole through which an ion beam passes,
a second member positioned opposite the first member and including a second beam passage hole through which the ion beam passes,
means for heating at least one of the first member and the second member and for blocking a flow of gas from entering a space between the first member and the second member.

15. The ion beam extraction electrode of claim 14, wherein the means comprises a heater that heats the at least one of the first member and the second member and that blocks the flow of gas from entering the space between the first member and the second member.

16. The ion beam extraction electrode of claim 14, wherein the means comprises a heater and a portion of the second member that both heats the at least one of the first member and the second member and at least a portion of the second member and blocks the flow of gas from entering the space between the first member and the second member.

17. The ion beam extraction electrode of claim 14, wherein the means comprises a heater that heats the at least one of the first member and the second member, and an inner edge and an outer edge of the second member that blocks the flow of gas from entering the space between the first member and the second member.

18. The ion beam extraction electrode of claim 14, wherein the means comprises a heater and a portion of an insulating member that both heats the at least one of the first member and the second member and blocks the flow of gas from entering the space between the first member and the second member.

19. The ion beam extraction electrode of claim 14, wherein the means comprises a heater that heats the at least one of the first member and the second member and a plurality of portions of an insulating member that blocks the flow of gas from entering the space between the first member and the second member.
